(19) United States
(12) Patent Application Publication
(10) Pub. No.: US 2023/0411198 A1
(43) Pub. Date: Dec. 21, 2023

(54) ARTICLE WITH A PROTECTIVE COATING

(71) Applicant: ASM IP Holding B.V., Almere (NL)

(72) Inventors: Joaquin Aguilar Santillan, Gilbert, AZ (US); Hong Gao, San Jose, CA (US); Shanker Kuttath, Austin, TX (US)

(21) Appl. No.: 18/208,421

(22) Filed: Jun. 12, 2023

Related U.S. Application Data
(60) Provisional application No. 63/352,535, filed on Jun. 15, 2022.

(51) Int. Cl. H01L 21/683

(52) U.S. Cl. CPC H01L 21/6833

(57) ABSTRACT

Various embodiment of the present technology may provide an article formed from a ceramic material. The article may further include a protective coating overlying one or more surfaces of the article. The protective coating may include a first layer including aluminum and magnesium and a second layer including alumina, or alumina and magnesium oxide.

### CROSS-REFERENCE TO RELATED APPLICATIONS

This application is a nonprovisional of, and claims priority to and the benefit of, U.S. Provisional Patent Application No. 63/352,535, filed Jun. 15, 2022 and entitled “METHODS AND APPARATUS FOR A SUBSTRATE WITH A PROTECTIVE COATING,” which is hereby incorporated by reference herein.

### FIELD OF INVENTION

The present disclosure generally relates to methods and apparatus for an article with a protective coating. More particularly, the present disclosure relates to an electrostatic chuck heater having a protective coating used in semiconductor manufacturing equipment.

### BACKGROUND OF THE DISCLOSURE

Electrostatic chuck (ESC) heaters used in semiconductor manufacturing may be formed from a ceramic material, such as aluminum nitride (AlN) due to its high thermal conductivity and power dissipation limit. However, the ceramic material may be prone to staining and/or uneven deposition on the ESC heater, which may cause performance issues (e.g., uneven heating) with the ESC heater. Accordingly, a protective coating that prevents the aforementioned issues may be desirable. Aluminum oxide (e.g., Al₂O₃) is a good candidate for the protective coating because it possesses excellent dielectric properties, is chemically neutral, and has good tribological characteristics. However, challenges exist in forming an aluminum oxide film on an aluminum nitride substrate.

### SUMMARY OF THE INVENTION

Various embodiment of the present technology may provide an article formed from a ceramic material. The article may further include a protective coating overlying one or more surfaces of the article. The protective coating may include a first layer including aluminum and magnesium and a second layer including alumina, or alumina and magnesium oxide.

According to one aspect, an apparatus comprises: an article formed from aluminum nitride, and comprising a first surface and a second surface; and a protective coating overlying at least the first surface, and comprising: a first layer comprising aluminum and magnesium; and a second layer comprising alumina.

In one embodiment, the second layer further comprises magnesium oxide.

In one embodiment, the ratio of magnesium oxide to alumina in the second layer is 200:10.

In one embodiment, the magnesium in the first layer has a concentration in a range of 1-500 ppm.

In one embodiment, the first layer directly interfaces with the article.

In one embodiment, the protective coating has a thickness in a range of 130 nm to 170 nm.

In one embodiment, the first layer has a thickness in a range of 10 nm to 50 nm.

In one embodiment, the second layer has a thickness in a range of 50 nm to 170 nm, and comprises nanocrystals having a diameter in a range of 30 nm to 40 nm.

In one embodiment, the protective coating has a first coefficient of thermal expansion (CTE) and the article has a second CTE; wherein the first CTE differs from the second CTE by a range of 25-50%.

According to another aspect, an electrostatic chuck comprises: an article comprising aluminum nitride, the article comprising a first, upward-facing surface and a second, opposing surface; a protective coating overlying the first surface, and comprising: a first layer comprising aluminum and magnesium; and a second layer comprising alumina; a plurality of electrodes embedded within the article; and a plurality of heating elements embedded within the article.

In one embodiment, the second layer further comprises magnesium oxide, and wherein a ratio of magnesium oxide to alumina in the second layer is 200:10.

In one embodiment, the magnesium in the first layer has a concentration in a range of 1-500 ppm.

In one embodiment, the protective coating has a thickness in a range of 130 nm to 170 nm.

In one embodiment, the first layer has a first thickness in a range of 10 nm to 50 nm, and wherein the second layer has a second thickness in a range of 50 nm to 170 nm.

In one embodiment, the second layer comprises nanocrystals having a diameter in the range of 30 nm to 40 nm.

According to yet another aspect, a system comprises: a reactor, comprising: a susceptor configured to hold a wafer and formed from a ceramic material, the susceptor comprising: a first, upward-facing surface and a second, opposing surface; a protective coating overlying the first surface, and comprising: a first layer comprising aluminum and magnesium; and a second layer, overlying the first layer, comprising alumina; a showerhead assembly disposed above the susceptor; and a source vessel coupled to the reactor and configured to contain a chemistry.

In one embodiment, the protective coating has a thickness in a range of 130 nm to 170 nm.

In one embodiment, the second layer further comprises magnesium oxide.

In one embodiment, the article comprises an electrostatic chuck comprising a body formed from aluminum nitride and a plurality of electrodes embedded within the body.

In one embodiment, the second layer comprises polycrystalline nanocrystals having a diameter in a range of 30 nm to 40 nm.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 representatively illustrates an apparatus in accordance with an embodiment of the present technology;

FIG. 2 is a graph illustrating the relationship between magnetron power and magnesium concentration in accordance with an embodiment of the present technology;

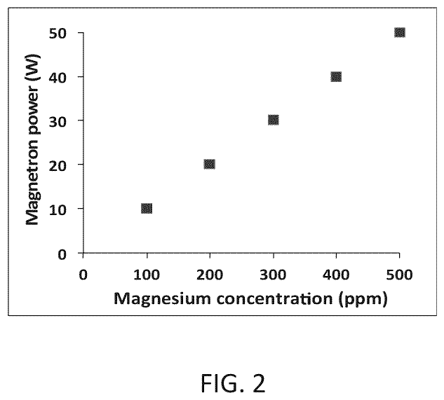

FIG. 3 is an image of a top view of a protective coating in accordance with an embodiment of the present technology;

FIG. 4 representatively illustrates an apparatus in accordance with an embodiment of the present technology;

FIG. 5 representatively illustrates an apparatus in accordance with an embodiment of the present technology;

FIG. 6 representatively illustrates an apparatus in accordance with an embodiment of the present technology; and

FIG. 7 is a block diagram of a system in accordance with an embodiment of the present technology.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

Reference will now be made to the drawings wherein like reference numerals identify similar structural features or aspects of the subject disclosure.

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of stated features.

The present disclosure relates to methods and apparatus for a substrate with a protective coating. More particularly, the present disclosure relates to an electrostatic chuck heater having a protective coating used in semiconductor manufacturing equipment.

As used herein, an article can refer to any material having a surface onto which material can be deposited. An article can include an electrostatic chuck heater used in processing a wafer. In other cases, the article can include any suitable workpiece, such as lift pins, gaskets, and the like.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of” or “consisting of” in some embodiments. In this disclosure, any defined meanings do not necessarily exclude ordinary and customary meanings in some embodiments.

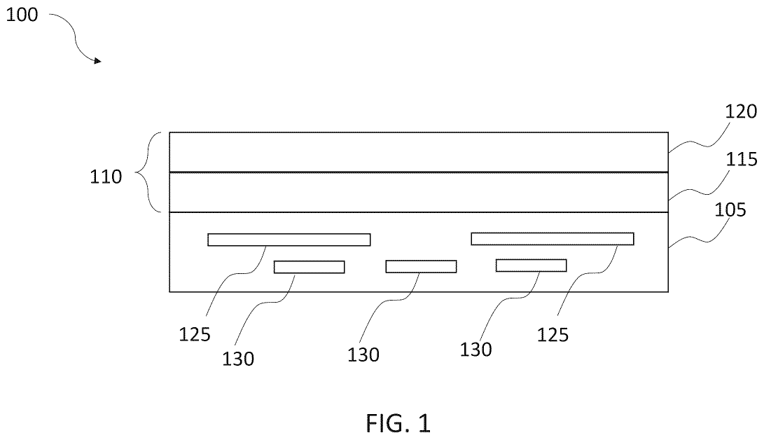

In various embodiments, and referring to FIGS. 1 and 4-6, an apparatus 100 may comprise an article 105 having a first surface and second surface, wherein the second surface opposes the first surface. The article 105 may be formed of or comprise a ceramic material (e.g., aluminum nitride (AlN)).

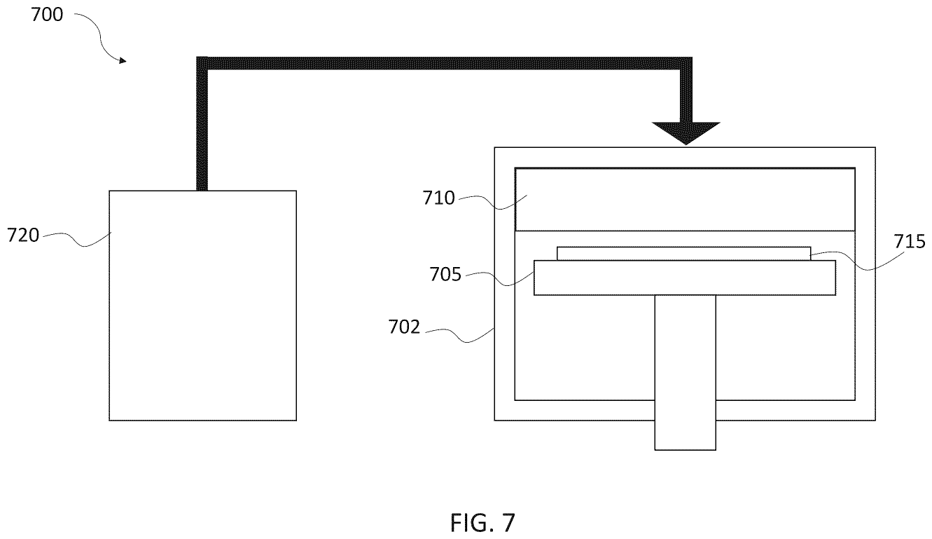

In various embodiments, the apparatus 100 may be a susceptor 705 (FIG. 7) configured to support a wafer 715. In some embodiments, the susceptor 705 may be an electrostatic chuck heater used to hold or clamp the wafer 715 using electrical force. In such an embodiment, the electrostatic chuck heater may comprise a plurality of electrodes 125 to form an electric field. In such cases, the article 105 may further comprise heating elements 130 and temperature sensors (e.g., thermocouples) (not shown) embedded within the article 105. The heating elements 130 may form any suitable pattern. The temperature sensors may be located at the edges of the substrate, the middle, and/or near a center of the article 105.

In various embodiments, the apparatus 100 may further comprise a protective coating 110 overlying the first surface of the article 105. The protective coating 110 may comprise one or more layers. For example, the protective coating 110 may comprise a first layer 115 and a second layer 120, wherein the first layer 115 is disposed directly on the first surface of the article 105 and the second layer 120 is disposed directly on the first layer 115. The first layer 115 may comprise aluminum and magnesium. The magnesium concentration in the first layer 115 may be in the range of 1-500 ppm (parts per million).

In one embodiment, the second layer 120 may comprise only alumina (AlOx). In another embodiment, the second layer 120 may comprise alumina and magnesium oxide, wherein the ratio of magnesium oxide to alumina is approximately 200:10. The thickness of the protective coating 110 may range from 130 nm to 170 nm. The thickness of the first layer 115 may range from nm. The thickness of the second layer 120 may range from 50-170 nm.

In various embodiments, the protective coating 110 may have a CTE (coefficient of thermal expansion) mismatch to the AlN article 105 of 25-50% difference.

In various embodiments, the apparatus 100 may further comprise a third layer (not shown) disposed between the article 105 and the first layer 115. The third layer may comprise yttrium, such as Y₂O₃, or yttrium aluminum garnet. The third layer may reduce stress between the article 105 and the first layer 115.

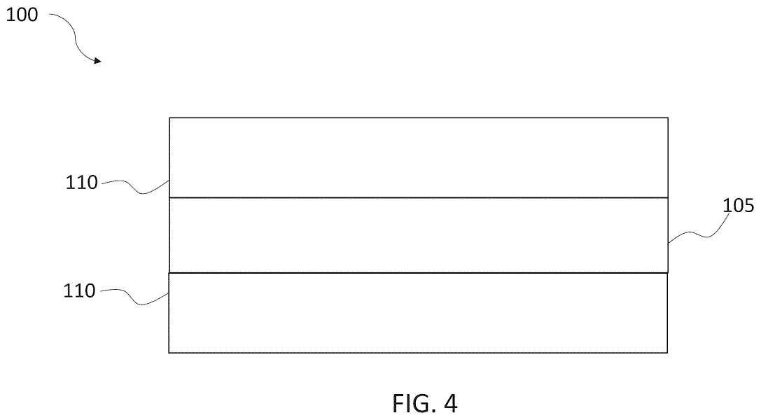

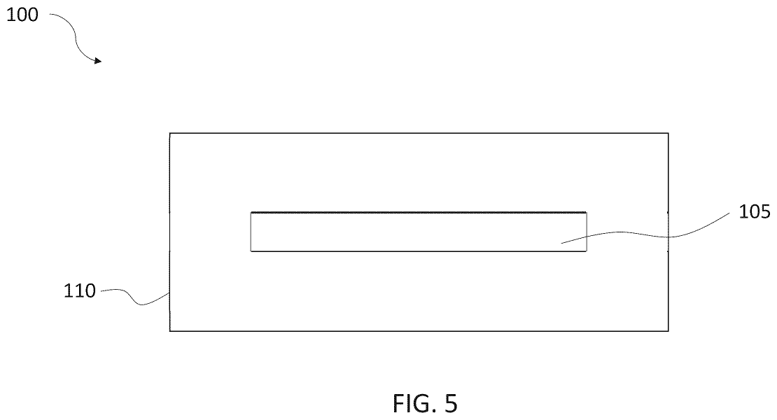

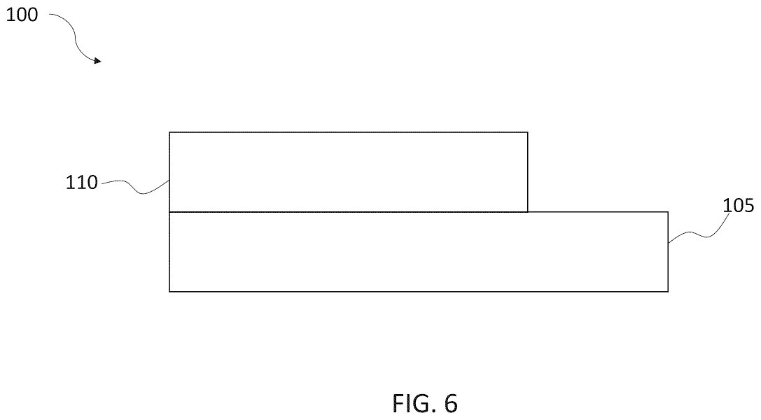

In various embodiments, the protective coating 110 may overlie a plurality of surfaces of the article 105. For example, the protective coating 110 may overlie the first surface and a second surface (for example, as illustrated in FIG. 4). In some embodiments, the protective coating 110 may encapsulate the article 105 (for example, as illustrated in FIG. 5). In some embodiments, the protective coating 110 may overly a portion of a surface, for example, a portion of the first surface (for example, as illustrated in FIG. 6).

The protective coating 110 may be formed by growing thin films using a thermal process (e.g., thermal atomic layer deposition), a magnetron sputtering system, or any other system suitable for growing films.

In the case of a magnetron sputter system, the sputtering system may operate at a high vacuum pressure (P=2×10⁻⁸ Torr, PO₂=1×10⁻⁸ Pa.). The sputtering system may be equipped with four, 2-inch magnetrons and a load lock used to introduce the article 105 into a growth chamber without losing the vacuum. The first layer 115 may be formed using high-purity Al (e.g., in the range of 98-99.99%). The article 105 may be placed adjacent to magnetrons, wherein the magnetrons have a confocal orientation that allows a uniform deposition with a standard deviation of 0.2% on the article 105. The growth of the protective coating 110 may be performed at room temperature (e.g., 20° C.) and the base pressure during metal deposition may be approximately 3×10⁻³ Torr.

In various embodiments, the magnetron sputtering creates a power density of 50 kW/cm2, which provides efficient evaporation of any ceramic target at high gas pressures (1-100 Pa). In this method, it is possible to prevent excessive heating of microelectronic devices, since the heating source is point-like and the surface being deposited can be distanced from the evaporated object. Accordingly, this method allows for depositing ceramic coatings at low temperatures. The method further comprises generating plasma that eliminates the problem of the electric charge accumulation on the article and, additionally, improves the chemical reactivity of gas, and preserves the surface stoichiometry Embodiments of the present technology deposit the protective coating 110 on the article 105 at rates up to tens of nm/min.

In various embodiments, the growth of the protective coating 110 may be performed by co-deposition of Al and Mg. The Al growth rate at 200 W using radio-frequency (rf) magnetron sputtering may be approximately 25 nm/min. The rate of deposition for a Mg concentration of 500 ppm on aluminum may be fixed to 0.07 nm/min at a power of 50 W using a rf-source.

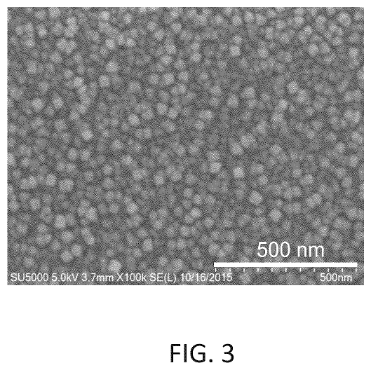

After deposition of the first layer 115, the vacuum pressure of oxygen may be lowered to 1×10⁻⁵ Pa to form thermodynamically an AlOx film (the second layer 120). As shown in FIG. 3, by way of imaging by a scanning electron microscope, the second layer 120 is constituted of nanocrystals having a diameter in the range of 30 nm to 40 nm, with an average diameter of 35 nm. The second layer 120 is polycrystalline due to the low growth temperature.

In various embodiments, the protective coating 110 may be deposited on the article 105 in-situ. However, in other embodiments, the protective coating 110 may be deposited on the sub state ex-situ.

Embodiments of the present technology provide an apparatus comprising a new ceramic composite material (including the article 105, the first layer 115, and the second layer 120) that can sustain high temperatures, while possessing excellent dielectric properties and being able to operate in aggressive media (e.g., reactive chemistries).

In various embodiments, the protective coating 110 may be a sacrificial coating, such that it may be removed from the article 105 by a wet chemistry or by a mechanical process. The protective coating 110 may then be reapplied to the article 105, if desired.

In various embodiments, and referring to FIG. 7, a system 700 may comprise a reactor 702 and a source vessel 720 in communication with the reactor 702. The source vessel 720 may be connected to the reactor 702 with a gas line and may contain a solid or liquid chemistry. Vapor or gas from the source vessel 720 may flow through the gas line to the reactor 702. The reactor 702 may comprise the susceptor 705 and a showerhead assembly 710. The showerhead assembly 710 may be disposed above the susceptor 705 and may be configured to deliver the gas or vapor to a chamber of the reactor 702. For example, the showerhead assembly 710 may comprise a plurality of through-holes.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

What is claimed is:

1. An apparatus, comprising:
an article formed from aluminum nitride, and comprising a first surface and a second surface; and
a protective coating overlying at least the first surface, and comprising:
a first layer comprising aluminum and magnesium; and
a second layer comprising alumina.

2. The apparatus according to claim 1, wherein the second layer further comprises magnesium oxide.

3. The apparatus according to claim 2, wherein the ratio of magnesium oxide to alumina in the second layer is 200:10.

4. The apparatus according to claim 1, wherein the magnesium in the first layer has a concentration in a range of 1-500 ppm.

5. The apparatus according to claim 1, wherein the first layer directly interfaces with the article.

6. The apparatus according to claim 1, wherein the protective coating has a thickness in a range of 130 nm to 170 nm.

7. The apparatus according to claim 1, wherein the first layer has a thickness in a range of 10 nm to 50 nm.

8. The apparatus according to claim 1, wherein the second layer has a thickness in a range of to 170 nm, and comprises nanocrystals having a diameter in a range of 30 nm to 40 nm.

9. The apparatus according to claim 1, wherein the protective coating has a first coefficient of thermal expansion (CTE) and the article has a second CTE; wherein the first CTE differs from the second CTE by a range of 25-50%.

10. An electrostatic chuck, comprising:
an article comprising aluminum nitride, the article comprising a first, upward-facing surface and a second, opposing surface;
a protective coating overlying the first surface, and comprising:
a first layer comprising aluminum and magnesium; and
a second layer comprising alumina;
a plurality of electrodes embedded within the article; and
a plurality of heating elements embedded within the article.

11. The electrostatic chuck according to claim 10, wherein the second layer further comprises magnesium oxide, and wherein a ratio of magnesium oxide to alumina in the second layer is 200:10.

12. The electrostatic chuck according to claim 10, wherein the magnesium in the first layer has a concentration in a range of 1-500 ppm.

13. The electrostatic chuck according to claim 10, wherein the protective coating has a thickness in a range of 130 nm to 170 nm.

14. The electrostatic chuck according to claim 10, wherein the first layer has a first thickness in a range of 10 nm to 50 nm, and wherein the second layer has a second thickness in a range of 50 nm to 170 nm.

15. The electrostatic chuck according to claim 10, wherein the second layer comprises nanocrystals having a diameter in the range of 30 nm to 40 nm.

16. A system, comprising:
a reactor, comprising:
a susceptor configured to hold a wafer and formed from a ceramic material, the susceptor comprising:
a first, upward-facing surface and a second, opposing surface;
a protective coating overlying the first surface, and comprising:
a first layer comprising aluminum and magnesium; and
a second layer, overlying the first layer, comprising alumina;
a showerhead assembly disposed above the susceptor; and
a source vessel coupled to the reactor and configured to contain a chemistry.

17. The system according to claim 16, wherein the protective coating has a thickness in a range of 130 nm to 170 nm.

18. The system according to claim 16, wherein the second layer further comprises magnesium oxide.

19. The system according to claim 16, wherein the article comprises an electrostatic chuck comprising a body formed from aluminum nitride and a plurality of electrodes embedded within the body.

20. The system according to claim 16, wherein the second layer comprises polycrystalline nanocrystals having a diameter in a range of 30 nm to 40 nm.
